(19) United States
(12) Patent Application Publication
(10) Pub. No.: US 2005/0160979 A1
(43) Pub. Date: Jul. 28, 2005

(54) Method and apparatus for applying a polycrystalline film to a substrate

(75) Inventors: Asher Grin, Jerusalem (IL); Barry N. Breen, Givat Ze'ev (IL); Haim Gilboa, Raanana (IL); Leonid Melekhov, Kiryat Ekron (IL)

Correspondence Address: SQUIRE, SANDERS & DEMPSEY L.L.P, 600 HANSEN WAY, PALO ALTO, CA, 94304-1043, US

(73) Assignee: Real-Time Radiography Ltd., Jerusalem (IL)

(21) Appl. No.: 11/043,641

(22) Filed: Jan. 25, 2005

Related U.S. Application Data
(60) Provisional application No. 60/538,511, filed on Jan. 26, 2004.

(51) Int. Cl. B05C 11/00; C23C 16/00

(52) U.S. Cl. 118/666; 427/248.1; 118/715

(57) ABSTRACT

A film deposition system for depositing a polycrystalline film on a large area substrate. The system includes a chamber formed of a set of walls, the set of walls defining at least three temperature zones within the chamber. Each of the walls is thermally insulated from the other walls forming the chamber. The system further includes a vacuum source, a set of heat sources, and a plurality of temperature detectors for detecting the temperature of the walls in the set of walls. Temperature control modules monitor and control the temperature in each of the temperature zones. The temperature control modules maintain predetermined temperatures in the walls so that the total mass of film-forming material lost through parasitic losses is less than the film mass deposited on the large area substrate. A method for depositing a polycrystalline film is also described.

This application claims the benefit of U.S. Provisional Application No. 60/538,511, to Grin et al, filed Jan. 26, 2004, entitled “Method and Apparatus for Applying a Polycrystalline Film to a Substrate,” which is incorporated herein by reference.

### FIELD OF THE INVENTION

The present invention relates to an apparatus, which is a film deposition system, and a method for applying a polycrystalline film to a substrate for use in high energy radiation detectors and imagers.

### DEFINITIONS

Substrate—either a unitary, single piece substrate or an array of small substrates being coated simultaneously.

Parasitic losses—material lost as a result of deposition of film-forming material anywhere in the film deposition system other than on the substrate intended to be coated.

Parasitic deposition—deposition of film-forming material anywhere in the film deposition system other than on the substrate intended to be coated.

Apparatus—used interchangeably herein with “film deposition system” without any intent at distinguishing between the terms.

### BACKGROUND OF THE INVENTION

Film deposition of various materials is used widely in the semiconductor industry as well as other areas of modern industry and technology. In one very general scenario a material with desired physical or chemical properties is deposited on a substrate of desired characteristics. Deposition is often effected by chemical vapor deposition (CVD) or physical vapor deposition (PVD). In PVD, the material is generally vaporized by heat and conveyed to a second cooler area in a closed system where the vaporized material condenses onto a substrate thereby forming a film. Many apparatuses have been designed to efficiently, and as rapidly as feasible, coat as many substrates as possible. FIG. 1 depicts a typical prior art film deposition system 100 which can be used to deposit Hgl₂ by direct physical vapor deposition. The apparatus consists of a two-part, vertical PYREX® or quartz ampoule 118 connected to a vacuum system 112. In FIG. 1, only the exit port of vacuum system 112 is shown. In the bottom part of ampoule 118 is a precursor source section 114, containing Hgl₂. The temperature, T_{precursor}, at the bottom of ampoule 118 is controlled and monitored separately by precursor heat controller 110. The upper part of ampoule 118 contains a substrate holder 108, to which the substrate is attached. Substrate holder 108 is locally heated by a resistance heater 122 or by radiative heat source 120. While both are shown in FIG. 1, it should be understood that in practice generally only one type of heat source is present. Heat sources 120 or 122 determine T_{subst}, the temperature of the substrate, and are controlled and monitored by heat controller 102. In order to provide the hot wall environment required, PYREX® or quartz ampoule 118 is introduced in a separately controlled, semi-transparent resistance furnace 124, the temperature of which is denoted as T_{furnace}. The temperature of ampoule 118 is controlled and monitored by heat controller 104.

Film deposition can occur if T_{furnace}>T_{precursor}>T_{subst}. Typical temperatures used are T_{furnace}=130° C., T_{precursor}=125° C., and T_{subst}=115° C.

It is possible to use prior art system 100 in FIG. 1 with wide band gap semiconductors other than Hgl₂. These include Pbl2, CdTe and CdZnTe. The latter two substances may be deposited as thin films on substrates such as Si with GaAs and used as infrared detectors. They can also be used to fabricate thick films for X-ray detectors.

The system in FIG. 1 is easily adaptable to evaporate Hg and I₂ separately followed by condensing them on the substrate where the elements form Hgl₂.

Other prior art physical vapor deposition systems are described and discussed by Iwanczyk et al in U.S. patent application Publication No. 2003/0021382 A1. The system described by Iwanczyk is based on equipment designed for single crystal formation employing glass ampoules and is limited to small substrates.

These prior art systems, however, do not optimize the working characteristics of the deposited films. They generally produce films with disoriented grains and in the case of Hgl₂, they do not produce dense c-axis columnar growth on the substrate. This latter feature is very desirable in optimizing the operating characteristics of high energy radiation detectors and imagers. Additionally, current deposition systems use more source material than is actually required because often the evaporated precursor material deposits on the side walls of the deposition chamber, on chamber flanges and hardware, and within the pumping system before the coating material arrives at the substrate. These parasitic losses of film-forming material lower vapor pressure in the coating chamber adversely affecting the quality of the deposited film. Finally, prior art systems have difficulty in depositing quality films on large area substrates.

### SUMMARY OF INVENTION

Described herein is an improved film deposition system and method for applying a polycrystalline film to a substrate. The polycrystalline films formed using the system and method are useful in direct detection of radiation, such as X-ray and gamma ray radiation.

It is an object of the present invention to provide a film deposition system, including a deposition chamber and ancillary elements, which allows for substantially optimal directional growth of films on large area substrates and where large voids are not found on the surface of the film.

It is a further object of the system to provide a film deposition system for physical vapor deposition that will allow for a more efficient use of the precursor source material by reducing parasitic deposition on areas of the system other than the large-area substrate. This reduction in parasitic deposition allows for better maintenance of the equilibrium vapor pressure in the deposition chamber and therefore produces better films.

It is yet another object of the present invention to provide a method for physical vapor deposition wherein large area substrates may be coated with negligible parasitic losses and wherein the film produced has optimal orientation and high density.

In one aspect of the present invention there is provided a film deposition system for depositing a polycrystalline film on a large area substrate. The system includes a chamber formed of a set of walls including a materials wall arranged in thermal communication with a film-forming material, a substrate retaining wall arranged in thermal communication with the large area substrate, and intermediate walls positioned between the materials and substrate walls. The set of walls defines a set of at least three temperature zones within the chamber, wherein each of the walls is thermally insulated from the other walls forming the chamber. The system also includes a vacuum source in gaseous communication with the chamber operative to evacuate the volume defined by the chamber and a plurality of temperature detectors for detecting the temperature of each of the walls in the set of walls. A different detector of the plurality of temperature detectors is positioned in each of the walls. The system further includes a set of heat sources of a number at least equal to the number of temperature zones and a set of temperature control modules at least equal in number to the number of temperature zones. The temperature of each of the zones in the set of temperature zones is monitored and controlled by a different control module, each of the modules in electrical communication with a different temperature detector from the plurality of detectors and with a different heat source. The heat source transfers heat to one or more walls adjacent to the zone whose temperature is controlled by the module. The temperature control modules maintain predetermined temperatures in the walls so that the total mass of film-forming material lost through parasitic losses is less than the film mass deposited on the large area substrate. In some embodiments, the walls are hollow or double walls or contain a conduit therein through which a temperature control fluid circulates.

In another aspect of the present invention there is provided a method for depositing a polycrystalline film on a large area substrate. The method includes the steps of:
providing and positioning the large area substrate and a film-forming material for deposition on the substrate in a film deposition chamber; and
forming at least three temperature zones within the walls of the evacuated film deposition chamber, each zone thermally insulated from and maintained at a temperature essentially distinct from the others with only one zone being maintained at or below a temperature wherein the rate of condensation of the vapor of a film-forming material is greater than the rate of evaporation of the material and where the substrate is positioned in the temperature zone having the lowest temperature.

This method allows for the formation of a highly oriented film on the substrate with the total mass of film-forming material lost through parasitic losses being less than the film mass deposited on the large area substrate.

In some embodiments, the method further includes the step of seeding the substrate.

In yet another aspect of the invention there is provided a radiation detection and imaging system which includes at least one detecting and imaging element comprising a large area substrate having a polycrystalline film deposited thereon substantially in accordance with the method described above.

### BRIEF DESCRIPTION OF THE DRAWINGS

The invention is herein described, by way of example only, with reference to the accompanying drawings. With specific reference to the drawings in detail, it is stressed that the particulars shown are by way of example and for purposes of illustrative discussion of the preferred embodiments of the present invention only. They are presented to provide what is believed to be the most useful and readily understood description of the principles and conceptual aspects of the invention. In this regard, no attempt is made to show structural details of the invention in more detail than is necessary for a fundamental understanding of the invention. The description of the invention below taken together with the drawings makes apparent to those skilled in the art how the several forms of the invention may be embodied in practice.

In the drawings:

FIG. 1 is a schematic view of a prior art Hgl₂ thin film deposition system;

FIG. 2 is a schematic view of a film deposition system constructed according to an embodiment of the present invention;

FIG. 3 is a schematic enlarged view of the coating chamber of the film deposition system shown in FIG. 2;

FIG. 4 is a graph of the relative temperatures in the various zones of the system shown in FIG. 1 when used to deposit Hgl₂;

FIGS. 5A and 5B are pictures of deposited Hgl₂ films using a prior art film deposition system and a film deposition system constructed according to an embodiment of the present invention, respectively; and

FIGS. 6A and 6B are XRD patterns of deposited Hgl₂ films using a prior art film deposition system and a film deposition system constructed according to an embodiment of the present invention, respectively.

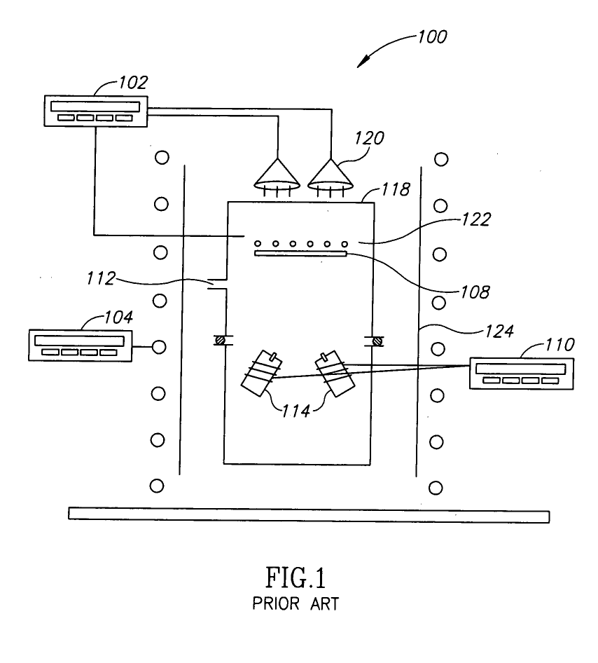

### DETAILED DESCRIPTION OF PREFERRED EMBODIMENTS

A non-equilibrium vapor pressure during film deposition in physical vapor deposition systems affects the quality of deposited films. This is especially true for large area substrates. Among other factors, parasitic losses lead to decreases in vapor pressure and non-equilibrium conditions in such systems.

While the effect of parasitic losses in coating small area substrates may be controllable without undue effort, this is not the case for large area substrates. The inventors have realized that a rigorous control of the deposition system by creating at least three distinct highly controlled temperature regimes therein allows for the production of high quality films. A method has been developed, and a film deposition system designed, that is based on rigorous temperature control. Such control allows for the maintenance of uniform temperatures throughout the substrate producing high quality films, particularly high quality wide band gap semiconductor films on large area substrates.

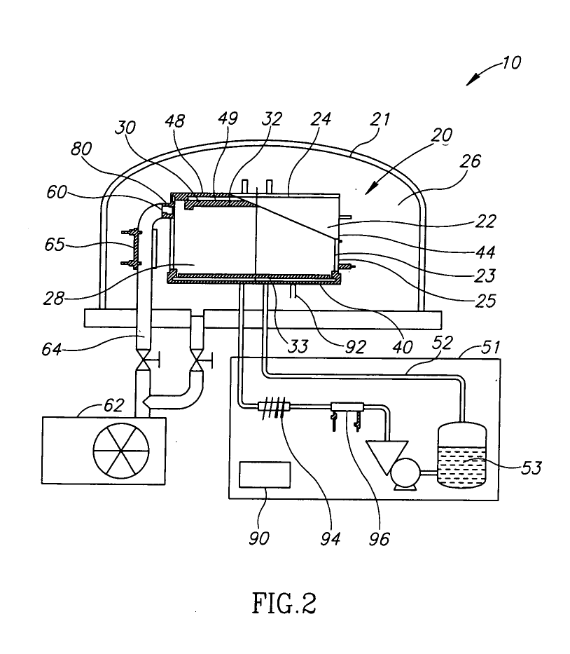

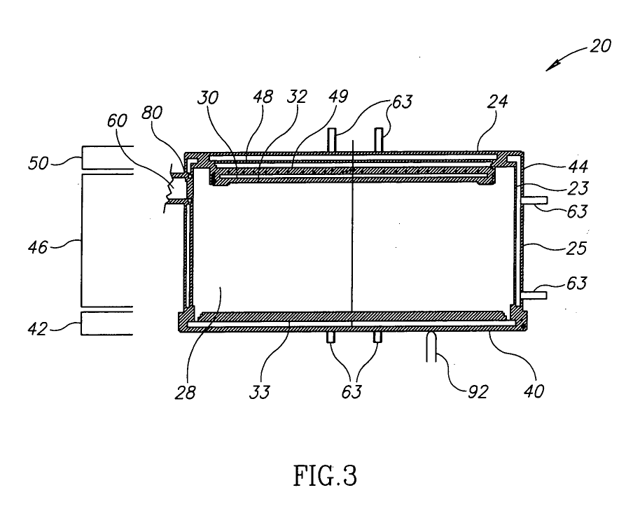

Reference is now made to FIG. 2 and FIG. 3 which illustrate an improved film deposition system 10 (FIG. 2) and an enlarged view of the coating chamber 20 (FIG. 3) of the system. Coating chamber 20 is positioned within bell jar 21, and chamber 20 finds especial utility in coating a substrate 30 with a polycrystalline film 32. Polycrystalline film 32 preferably includes a material suited for use in direct detection of electromagnetic radiation, including but not limited to, X-ray radiation. For example, film 32 may be composed primarily of Hgl₂.

In general, coating chamber 20 may be described as a group of walls 22, at least one of which includes a sealable aperture 24 for introduction of a substrate 30. Walls 22 define an interior space 28 which is separated from outside environment 26 when aperture 24 is closed. Each of walls 22 may be described as having an inner face 23 proximal to interior space 28 and an outer face 25 which contacts outside environment 26.

In order to aid in the description, each of walls 22 is assigned to one of three zones, a materials wall 40 belonging to a first temperature zone 42, side walls 44 belonging to a second temperature zone 46 and a substrate retaining wall 48 belonging to a third temperature zone 50.

Substrate retaining wall 48 is configured to be able to hold a variety of large area arrays including 8″×8″ and 17″×17″ arrays. Additionally or alternately, the size of chamber 20 may be configured according to the size of substrate 30 with a small chamber being used for processing a 5″×5″ array substrate, a larger one for processing an 8″×8″ array substrate and an even larger one for processing a 17″×17″ array substrate. While the substrate has been described as an array, it is readily understood that a single piece substrate, herein also referred to as a unitary substrate, of similar sizes may also be used. When the term “substrate” is used herein, it contemplates both unitary and array type substrates.

Additionally, when the term “large area substrate” is used herein, the term generally refers to substrates in excess of 25 square inches and includes substrates up to 900 square inches. It should readily be understood by one skilled in the art that smaller substrates may also be coated using the film deposition system of the present invention and the term “large area substrates” is not meant to preclude the system's use for small area substrates.

Chamber 20 is further equipped with at least one exhaust port 60 which provides a channel for gas communication between interior space 28 and outside environment 26 by means of a conduit 64. Exhaust port 60 is preferably connected to a vacuum source 62 by means of a conduit 64. This arrangement insures a unidirectional flow of gasses from interior space 28 to vacuum source 62 during operation of chamber 20. The vapor pressure of the evaporated material should be maintained as close as possible to equilibrium in accordance with the temperature of material 33. Material 33 is placed proximate to or on materials wall 40, which determines the temperature of the material 33.

A heat shield 80 is preferably installed in proximity to exhaust port 60 to minimize parasitic loss of vapor to vacuum source 62 and conduit 64. A trap 65 may be employed to absorb any vapor that may be sucked into conduit 64. Preferably trap 65, in communication with conduit 64, is a cooled trap.

Preferably, the temperature in each of zones 42, 46 and 50 is independently controlled by a temperature control module 51. Module 51 may include, for example, a central control unit 90, at least one temperature -detector 92 in communication (not shown) with control unit 90, a heating unit 94, a cooling unit 96, at least one temperature control channel 52 which facilitates flow of a temperature control fluid 53 within walls 22, a supply of temperature control fluid 53, and a pumping/switching apparatus (not shown) for directing fluid 53 of a desired temperature to channels 52 and then to walls 22 in zones 42, 46 and 50 as required. Central control unit 90 is preferably a computer with suitable control interfaces to all other components of module 51. However, a mechanical, electronic or other control unit 90 with comparable function may be employed without significantly altering the performance of coating chamber 20. Temperature control fluid 53 may be, for example, an oil, a polymer, or an aqueous solution.

For simplicity of presentation, FIG. 2 shows only a single temperature control module 51. However, it should be noted that there are typically three independent such modules one to control the temperature of the walls in each of the different zones 42, 46 and 50. What are shown in FIGS. 2 and 3 are fluid input and exit ports 63 for each of the three temperature control modules 51 controlling each of the three zones. In general, the number of temperature control modules equals, or may be greater than, the number of temperature zones in the system.

Similarly, FIG. 2 and FIG. 3 show only a single temperature detector 92. It should be understood that while not shown, each of zones 42, 46 and 50 would have at least one such detector 92 positioned in its walls.

Unlike the coating chambers of prior art physical vapor deposition systems used to deposit polycrystalline detector films which are typically made of glass, the chamber in FIGS. 2 and 3 can be, and typically is, made of other materials, such as stainless steel. The greater freedom in selecting materials from which to fabricate the film deposition system of the present invention allows for systems that can coat substrates of much larger areas.

In order to deposit film 32 on substrate 30, a reservoir of material 33 (e.g. Hgl₂) is placed on materials wall 40 in first temperature zone 42. Substrate 30 is attached to substrate retaining wall 48 in third temperature zone 50 so that one face of substrate 30 is positioned within interior space 28. “Attached”, as used herein, includes, but is not limited to, bringing a significant portion of a surface of substrate 30 in proximity to, or making contact with, substrate retaining wall 48 so that conductive and/or radiant heat from wall 48 controls the temperature of substrate 30. Aperture 24 is close to the size of substrate retaining wall 48. In some embodiments, a thermally conductive glue may be used to attach substrate 30 to substrate retaining wall 48. In other embodiments, the substrate is retained in a holder positioned proximate to, and generally in contact with, substrate retaining wall 48.

Preferably, substrate 30 is in very good thermal contact (convection or conduction) with substrate retaining wall 48 thus ensuring even temperature distribution across substrate 30. Alternately, a defined gap between substrate 30 and substrate retaining wall 48 may ensure even temperature distribution across substrate 30. Additionally or alternately, a material 49, for example Teflon, may be disposed between the heated substrate retaining wall 48 and substrate 30 in order to assure uniformity of temperature throughout substrate 30. It is an important feature of chamber 20 that it facilitates accurate control of the temperatures in zones 42, 46 and 50. For example, if material 33 is Hgl₂, it is desirable to achieve a temperature in zone 42 in the range of 40 to 160 degrees centigrade, more typically 90-130 degrees centigrade, to cause sublimation of material 33 placed on materials wall 40 when interior space 28 is at a pressure of 0.1 to 1000 mT, typically 10 to 100 mT. This pressure is achieved by use of vacuum source 62 applied to exhaust port 60 as described hereinabove. In order to assure that material 33 remains in the gas phase, the temperature in interior space 28 must be maintained near the sublimation temperature applied to material 33 by zone 42. This means that walls 44 of zone 46 must be maintained near the temperature of zone 42. The exact optimum temperature of zone 46 is a function of the size and geometry of interior space 28.

In order to cause recrystallization of material 33 on a surface of substrate 30, thereby creating film 32 on substrate 30, the temperature of wall 48 of zone 50 is preferably below that of zone 42 the sublimation temperature of material 33. For example, a temperature in zone 50 of 5 to 25 degrees centigrade below the temperature of zone 42 may be employed. Use of the system of the present invention typically results in the total mass of film-forming material lost through parasitic deposition being less than the mass of the film deposited on the large area substrate.

In one comparative experiment, the system of the present invention produced a substrate coated with about two-thirds of the evaporated film-forming material. The remaining one-third constituted parasitic deposition. When a prior art deposition system was used, only about 40% of the evaporated film-forming material deposited on the substrate. The remaining about 60% deposited on the walls, flanges, etc. of the system.

The experimental conditions above are typical, but non-limiting, conditions for Hgl₂ film deposition; for other materials other conditions are of course required.

It should readily be appreciated that in other embodiments more than three temperature zones may be required for film deposition on a substrate. In such circumstances, there will typically be separate temperature control modules with independent temperature detectors for each of the zones.

In other embodiments of the invention, the heat source may be a radiative heat source, such as an IR lamp, or an electrical resistance source and not necessarily a temperature control fluid as in FIGS. 2 and 3. Again, the number of heat sources will typically be equal to the number of temperature zones and generally each heat source will be controlled separately. Heat sources, of whatever type, heat the walls of chamber 20 directly. The heated walls in turn determine the temperature of the various zones within chamber 20.

The design of a multi-temperature zone system, an example of which has been described in conjunction with FIGS. 2 and 3, is intended to reduce deposition of the film-forming material on parasitic surfaces (flanges, walls etc.) and not on the substrate. These parasitic losses cause chamber (reactor) vapor pressure to be lower than it would normally be relative to the source temperature i.e. not at equilibrium, resulting in longer deposition times, higher deposition cost, and poorer quality films.

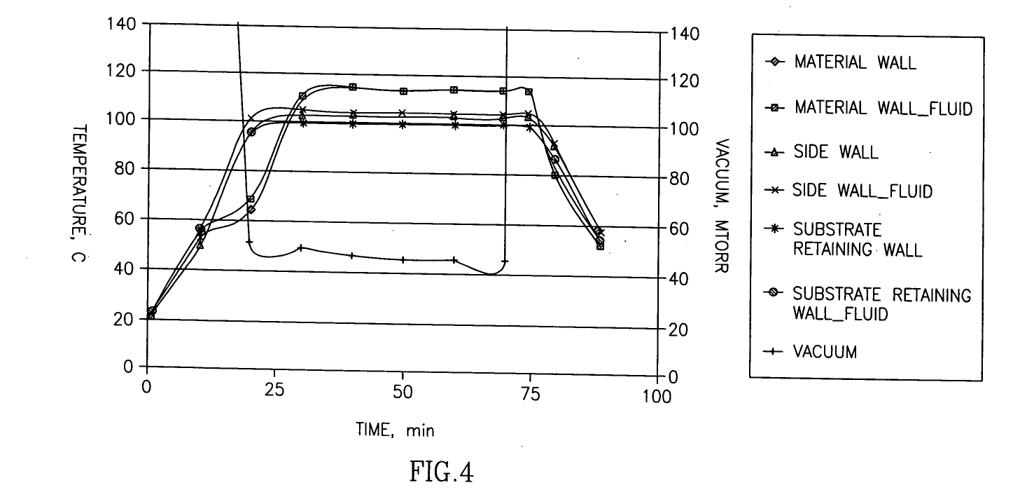

FIG. 4, to which reference is now made, shows a typical heating profile of each of the temperature zones in the system shown in FIG. 2, as well as the pressure profile of the vacuum. These are typical conditions when Hgl₂ is used as a source material and when the substrate is an 8″×8″ glass substrate.

FIG. 4 shows that there is a slight ramping up of the temperature when heating the source material followed by a delay in the heating (in FIG. 4 occurring approximately between 10-20 minutes). Heating the source material to its final temperature is delayed until the walls and substrate temperatures are substantially stabilized at their desired temperatures. The initial ramping is required to protect an Hgl₂ seed layer on the substrate. As discussed below, seeded substrates are typically used with the system of the present invention, the seeding being effected prior to deposition. The subsequent delay in heating the source material is required to slow film growth rate until optimum substrate temperature is reached, ensuring good quality deposited films.

FIG. 4 shows that the temperatures of the walls when stabilized are essentially identical to the temperature of the temperature control fluid in the heating system for that zone. The temperature control fluid heats the walls by passing through a cavity or hollow conduit-like structure within the walls and then returns to temperature control module 51 (FIG. 2). In many cases, the walls of chamber 20 (FIGS. 2 and 3) are double walled. In yet other embodiments, a conduit, generally coiled, through which a temperature control fluid flows, may be attached to the outside faces of the walls of chamber 20.

Also important to note in FIG. 4 is the relative small difference between the source material wall and side wall temperatures. This small temperature differential reduces parasitic losses of the film-forming material i.e. source material. During the latter part of the ramp up stage, the temperatures of the side walls and substrate retaining wall are maintained at temperatures that are high relative to the source material temperature. Substantial film growth is therefore retarded as a result of reevaporation from the substrate until Tsource>Tsubstrate and Tsource>Tside walls. Similarly, parasitic losses from the side walls are minimized during this stage since any deposited vapor reevaporates.

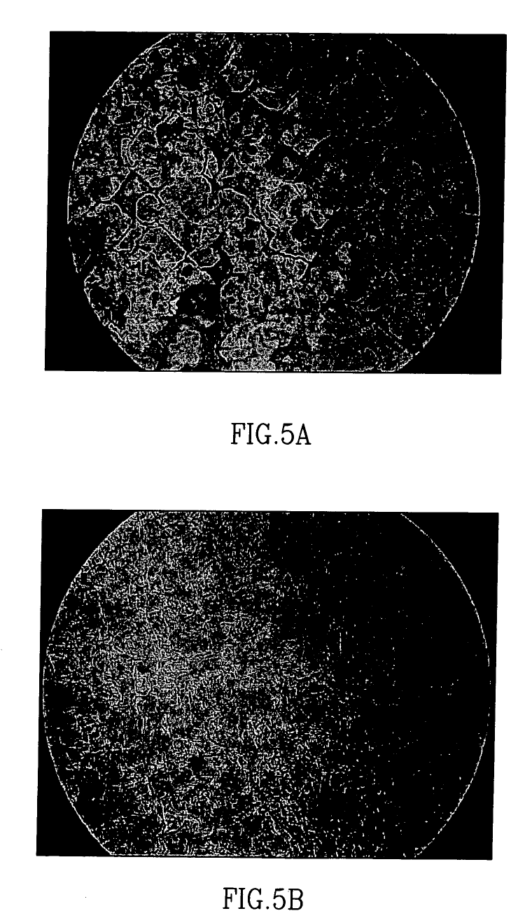

FIG. 5A and FIG. 5B show an optical microscopic view of Hgl₂ films deposited using a prior art film deposition system and a film deposition system constructed according to an embodiment of the present invention, respectively. In both cases the substrate is an 8″×8″ glass substrate. The substrates in both figures have been seeded in a manner described in U.S. patent application Publication No 2004/0232347 to Melekhov et al incorporated by reference herein in its entirety.

In the Melekhov et al application, seeding of small substrates (less than about 5″×5″) is discussed. In the present application, the seeding method described in Melekhov has been applied to larger substrates.

FIG. 5A shows a film deposited on a large area seeded substrate using a prior art film deposition system. The film has low density, irregular grain boundaries and an essentially non-c-axis columnar morphology. FIG. 5B, on the other hand, shows the essentially uniform grain boundaries, high density, c-axis columnar orientation of an Hgl₂ film deposited on a large area seeded substrate using a film deposition system constructed according to the present invention. It is readily seen that the top of the film in FIG. 5B is smooth without voids while the opposite is true in the film of FIG. 5A. This is thought to be the result of the deposition system used in FIG. 5B in which the Hgl₂ grains are deposited at a uniform rate, thereby eliminating the possibility of their clustering in groups.

The value of essentially c-axis oriented columnar Hgl₂ films in optimizing the detection and imaging features of the film has been discussed previously such as in U.S. patent application Publication No. 2004/0232347 A1 to Melekhov et al, incorporated by reference herein in their entirety.

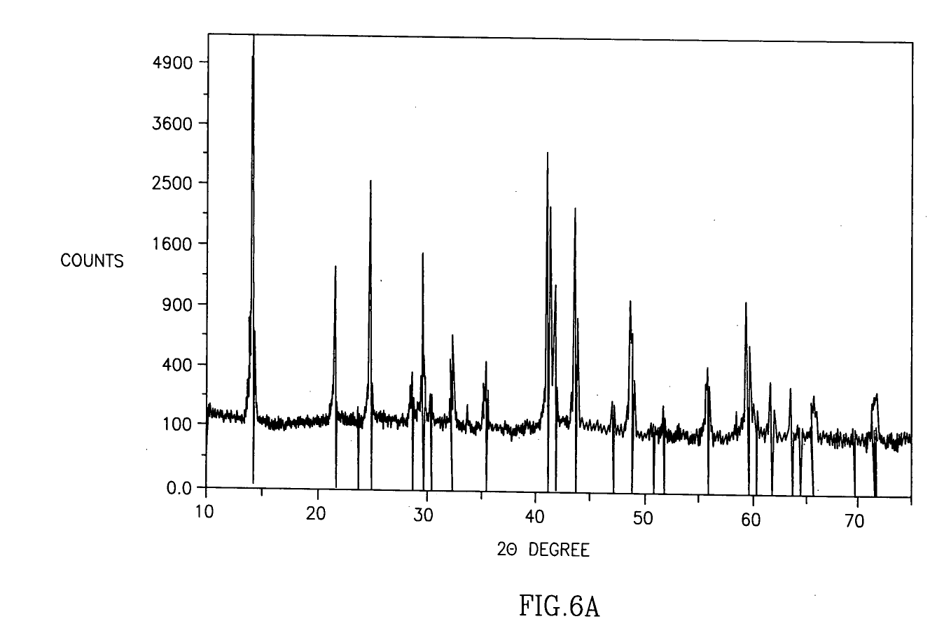

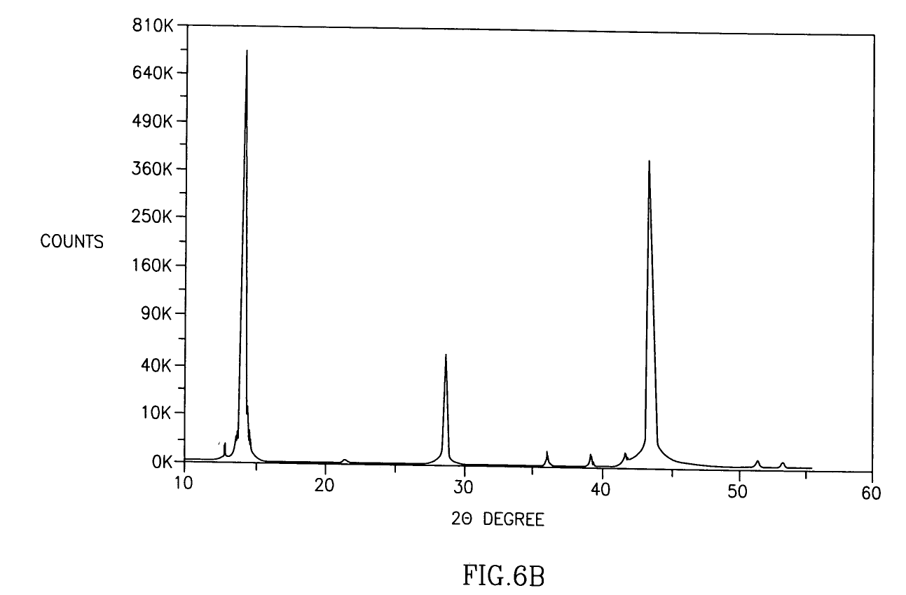

Reference is now made to FIGS. 6A and 6B which show XRD patterns for films made using a prior art film deposition system and a film deposition system constructed according to an embodiment of the present invention, respectively. The substrates for both films have been seeded prior to film deposition using the method described in U.S. patent application Publication No. 2004/0232347 to Melekhov et al mentioned above. FIG. 6A shows a film with disorientated grains while FIG. 6B shows a very desirable film having highly oriented grains and possessing columnar structure and c-axis orientation. As noted above, the desirability of such orientation for Hgl₂ detectors and imagers of electromagnetic radiation has been discussed elsewhere. When using other deposition materials, the ability to finely control temperatures allows for deposition of the source materials on substrates in their most preferred orientations while minimizing parasitic losses within the system.

The embodiments of the deposition system of the present invention can be used to deposit films of many different wide band gap semiconductors useful for detecting X-rays and gamma rays. These include, but without any intent at being limiting, mercuric iodide, lead iodide, bismuth iodide, cesium iodide, thallium bromide, cadmium telluride and cadmium zinc telluride (CZT).

While the embodiment in FIGS. 2 and 3 relates to a film deposition system that has three temperature zones, it is contemplated within the scope of the invention that some deposition processes may require additional zones. Accordingly, in such systems the system may have more than three temperature control modules, heat sources and temperature detectors, each module, heat source and detector used to modulate and control the temperature in a different temperature zone.

In the embodiment of FIGS. 2 and 3, the separation and isolation of the three temperature zones is effected by positioning insulating O-rings between the top substrate retaining wall and the side walls and between the bottom materials wall and the side walls. The movement of heat from hotter walls to cooler walls in the system is thereby prevented. When more than three zones are used, effective insulation material must be positioned at the wall interfaces of the different zones to maintain their temperature stability and isolate each zone from temperature differentials between it and the other zones in the system. Materials, such as ceramic materials, silicon polymers, TEFLON®, VITON®, and other fluoropolymers may be used to effect the insulation; these materials are exemplary only and are not intended to be limiting.

In summary, as noted above, parasitic losses cause reactor, i.e. chamber 20 (FIGS. 2 and 3), vapor pressure to be lower than it should be for a given source temperature and pressure, i.e. not in equilibrium. This negatively affects film quality. For smaller substrates and reactors, process windows can be found which are not impaired by such parasitic losses, particularly when seeding is effected in the manner described above in U.S. patent application Publication No. 2004/0232347 A1 to Melekhov et al. However, for larger substrates and the larger reactors (chambers) they require, seeding alone can not overcome the negative effects of parasitic losses. The film deposition system and method discussed herein are required to reduce the affect of parasitic losses so that good quality films on large area substrates can be obtained.

The present invention also provides a method for overcoming the affects of parasitic losses when depositing a polycrystalline film on a large area substrate. The method includes the steps of:
providing and positioning the large area substrate and a film-forming material for deposition on the substrate in a film deposition chamber; and
forming at least three temperature zones within the walls of the evacuated film deposition chamber, each zone thermally insulated from and maintained at a temperature essentially distinct from the others with only one zone being maintained at or below a temperature wherein the rate of condensation of the vapor of a film-forming material is greater than the rate of evaporation of the material and where the substrate is positioned in the temperature zone having the lowest temperature,
thereby allowing for the formation of a highly oriented film on the substrate with the total mass of film-forming material lost through parasitic losses being less than the film mass deposited on the large area substrate.

In some embodiments, the method further includes the step of seeding the substrate prior to the step of providing and positioning. In these embodiments the film-forming material may be Hgl₂.

In yet other embodiments of the method, the step of forming includes forming a first, a second and a third temperature zone where the temperatures of the walls are maintained at predetermined temperatures T1, T2, and T3 respectively, the second temperature zone being the zone wherein the rate of condensation of the vapor of the film-forming material is greater than the rate of the evaporation of the material; and
the step of providing and positioning further includes the steps of:
positioning the film-forming material in the first temperature zone where its temperature is controlled at the first predetermined temperature T1 so that a phase change may occur and the material may be evaporated;
positioning the substrate in the second temperature zone where its temperature is controlled at the second predetermined temperature T2, T2 being the temperature wherein the rate of condensation exceeds the rate of evaporation of the film-forming material, and
wherein the third temperature zone is situated between the substrate and the film-forming material wherein the third predetermined temperature T3 is controlled to allow the evaporated film-forming material to remain substantially as a vapor as it moves through the chamber toward the substrate for deposition thereon substantially without parasitic deposition in other parts of the chamber.

The relationship between T1, T2 and T3 can be such that either T1≧T3>T2, or T1>T2 and T1≦T3>T2.

In some embodiments of the method, the third temperature zone is divided into two or more temperature zones within the walls of the third zone. Each zone is thermally insulated from the others. Each of these additional zones has its temperature controlled by a different temperature control module in communication with a different heat source. Each additional zone is controlled at a temperature different from the temperatures of the other zones.

In some embodiments of the method of the present invention, the step of forming includes the step of ramping the temperature in the three temperature zones. The temperature of the zone in which the film-forming material is positioned is ramped initially at about the same rate as the temperatures in the other two zones and then held substantially constant until the temperatures in the other two zones have been ramped to substantially their final temperatures. Then ramping of the temperature of the zone in which the film-forming material is positioned is continued until its predetermined final temperature is reached.

In the method of the present invention, each temperature zone is controlled by a separate temperature control module and each module is in thermal communication with a different heat source, each heat source delivering heat to its respective temperature zone.

In some embodiments of the method, each of the different heat sources contains a temperature control fluid which is maintained at a predefined temperature and delivered to and circulated through hollow walls of an apparatus proximate to a predetermined temperature zone. In other embodiments, each of the different heat sources contains a temperature control fluid which is maintained at a predefined temperature and delivered to and circulated through conduits positioned in the walls, or attached thereto, of an apparatus proximate to a predetermined temperature zone.

The method can be used to form a film, wherein the film-forming material is Hgl₂ and wherein the film deposited using the method exhibits an XRD pattern substantially as shown and illustrated in FIG. 6B. Similarly, the method can be used to form a film wherein the film-forming material is Hgl₂ and wherein the film deposited using the method exhibits a highly oriented, dense morphology with a smooth surface substantially as shown and illustrated in FIG. 5B.

The substrates on which the films are deposited by using the method of the present invention may be large area substrates. The method of the present invention can be used to deposit films of many different wide band gap semiconductors useful for detecting X-rays and gamma rays. These include, but without any intent at being limiting, mercuric iodide, lead iodide, bismuth iodide, cesium iodide, thallium bromide, cadmium telluride and cadmium zinc telluride (CZT).

The present invention also teaches a large area substrate having a highly oriented polycrystalline film deposited thereon, the film deposition effected by the method described herein above. Additionally, it teaches a radiation detection and imaging system which includes at least one detecting and imaging element comprising a large area substrate having a polycrystalline film deposited thereon, the film deposition effected by the method discussed herein above. The film on the large area substrate deposited by the herein above described method may be a mercuric iodide film.

The present invention also teaches a large area substrate having a highly oriented mercuric iodide polycrystalline film deposited thereon, the film having an XRD pattern substantially as shown and illustrated in FIG. 6B. Additionally, it teaches a radiation detection and imaging system which includes at least one detecting and imaging element comprising a large area substrate having a polycrystalline mercuric iodide film deposited thereon, the film having an XRD pattern substantially as shown and illustrated in FIG. 6B.

Radiation and imaging systems using the wide band gap semiconductor coated large area substrates discussed in the present application may be fabricated and constructed by any of the many methods known to those skilled in the art. One such construction is described in U.S. Pat. No. 5,892,227 to Schieber et al, the document herein incorporated by reference in its entirety.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

Although the invention has been described in the text and illustrated in the Figures in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. Further, the order of the steps of the method outlined herein is not intended to impose a particular order of the steps. It is to be understood that the phraseology and terminology employed herein is for the purpose of description and should not be regarded as limiting.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. A film deposition system for depositing a polycrystalline film on a large area substrate, said system comprised of:
a chamber formed of a set of walls including a materials wall arranged in thermal communication with a film-forming material, a substrate retaining wall arranged in thermal communication with the large area substrate, and intermediate walls positioned between said materials wall and said substrate wall, said set of walls defining at least three temperature zones within said chamber, wherein each of said walls is thermally insulated from the other walls forming said chamber;
a vacuum source in gaseous communication with said chamber operative to evacuate the volume defined by said chamber;
a plurality of temperature detectors for detecting the temperature of each of said walls in said set of walls, a different detector of said plurality of temperature detectors being positioned in each of said walls;
a set of heat sources of a number at least equal to the number of temperature zones;
a set of temperature control modules of a number which is at least equal to the number of temperature zones and wherein the temperature of each of the zones is monitored and controlled by a different control module, each of said modules in electrical communication with a different temperature detector and with a different heat source which transfers heat to one or more walls adjacent to the zone whose temperature is controlled by said module, said temperature control modules operative to maintain predetermined temperatures in said walls so that the total mass of film-forming material lost through parasitic losses is less than the film mass deposited on the large area substrate.

2. A film deposition system according to claim 1 wherein said chamber further includes a heat shield proximate to a port leading to said vacuum source thereby reducing parasitic losses around said port and losses in a conduit leading from said port to said vacuum source.

3. A film deposition system according to claim 1 wherein each wall in said set of walls is a double wall between and through which a temperature control fluid at a predetermined temperature is delivered from one of said heat sources and returned to said heat source and wherein each of said temperature control modules further includes a means for pumping said temperature control fluid through said double walls.

4. A film deposition system according to claim 1 wherein each wall in said set of walls contains at least one conduit through which a temperature control fluid at a predetermined temperature is delivered from one of said heat sources and returned to said heat source and wherein each of said temperature control modules further includes a means for pumping said temperature control fluid through said conduits.

5. A film deposition system according to claim 1 wherein said heat sources are selected from a group consisting of radiative heat sources and electrically resistive heat sources, said sources positioned proximate to said set of walls.

6. A film deposition system according to claim 1 wherein said heat sources are selected from a group consisting of radiative heat sources and electrically resistive heat sources, said sources positioned within said set of walls.

7. A film deposition system according to claim 1 further including a substrate holder sized and configured to hold the large area substrate in good thermal communication with said substrate wall and wherein said substrate holder is positioned adjacent to said substrate wall.

8. A film deposition system according to claim 7 wherein said substrate holder is positioned so that a heat diffusing material may be positioned between said substrate wall and said substrate holder so as to ensure a uniform temperature throughout the substrate.

9. A film deposition system according to claim 1 wherein said system is sized and configured to allow deposition of films on substrates of up to about 900 square inches.

10. A film deposition system according to claim 1 wherein the film-forming material is a wide band gap semiconductor.

11. A film deposition system according to claim 10 wherein the wide band gap semiconductor is selected from the group consisting of mercuric iodide, lead iodide, bismuth iodide, thallium bromide, cesium iodide, cadmium telluride, and cadmium zinc telluride (CZT).

12. A method for depositing a polycrystalline film on a large area substrate, said method comprising the steps of:
providing and positioning the large area substrate and a film-forming material for deposition on the substrate in a film deposition chamber; and
forming at least three temperature zones within the walls of the evacuated film deposition chamber, each zone thermally insulated from and maintained at a temperature essentially distinct from the others with only one zone being maintained at or below a temperature wherein the rate of condensation of the vapor of the film-forming material is greater than the rate of evaporation of the material and where the substrate is positioned in the temperature zone having the lowest temperature,
thereby allowing for the formation of a highly oriented film on the substrate with the total mass of film-forming material lost through parasitic losses being less than the film mass deposited on the large area substrate.

13. A method according to claim 12, further including the step of seeding the substrate prior to said step of providing and positioning.

14. A method according to claim 13 wherein the film-forming material is Hgl₂.

15. A method according to claim 12, wherein said step of forming includes forming a first, a second and a third temperature zone where the temperatures are maintained at predetermined temperatures T1, T2, and T3 respectively, the second temperature zone being the zone wherein the rate of condensation of the vapor of the film-forming material is greater than the rate of evaporation of the material; and
said step of providing and positioning further includes the steps of:
positioning the film-forming material in the first temperature zone where its temperature is controlled at the first predetermined temperature T1 so that a phase change may occur and the material may be evaporated;
positioning the substrate in the second temperature zone where its temperature is controlled at the second predetermined temperature T2, T2 being the temperature wherein the rate of condensation exceeds the rate of evaporation of the film-forming material, and
wherein the third temperature zone is situated between the substrate and the film-forming material wherein the third predetermined temperature T3 is controlled to allow the evaporated film-forming material to remain substantially as a vapor as it moves through the chamber toward the substrate for deposition thereon substantially without parasitic deposition in other parts of the chamber.

16. A method according to claim 15 wherein the third temperature zone is divided into two or more temperature zones within the walls of the third temperature zone, each zone thermally insulated from the other zones.

17. A method according to claim 15 wherein T1≧T3>T2.

18. A method according to claim 15 wherein T1>T2 and T1≦T3>T2.

19. A method according to claim 12 wherein said step of forming includes the step of ramping the temperature in the three temperature zones wherein the temperature of the zone in which the film-forming material is positioned is ramped initially at about the same rate as the temperatures in the other two zones are ramped and then held substantially constant until the temperatures in the other two zones have been ramped to substantially their final temperatures after which ramping of the temperature of the zone in which the film-forming material is positioned is continued until the predetermined final temperature of that zone is reached.

20. A method according to claim 12, wherein each temperature zone is controlled by a separate temperature control module and each module is in thermal communication with a different heat source, each heat source delivering heat to its respective temperature zone.

21. A method according to claim 20, wherein each of the different heat sources contains a temperature control fluid which is maintained at a predefined temperature and delivered to and circulated through hollow walls of an apparatus proximate to a predetermined temperature zone.

22. A method according to claim 20, wherein each of the different heat sources contains a temperature control fluid which is maintained at a predefined temperature and delivered to and circulated through conduits positioned in the walls of an apparatus proximate to a predetermined temperature zone.

23. A radiation detection and imaging system which includes at least one detecting and imaging element comprising a large area substrate having a polycrystalline film deposited thereon substantially in accordance with the method of claim 12.

24. A radiation detection and imaging system according to claim 23 wherein said polycrystalline film is a mercuric iodide film.

25. A large area substrate having a polycrystalline film deposited thereon substantially in accordance with the method of claim 12.

26. A large area substrate according to claim 25 wherein said polycrystalline film is a mercuric iodide film.

27. A large area substrate having a highly oriented polycrystalline mercuric iodide film deposited thereon said film having an XRD pattern substantially as shown and illustrated in FIG. 6B.

28. A radiation detection and imaging system which includes at least one detecting and imaging element comprising a large area substrate having a polycrystalline mercuric iodide film deposited thereon, said film having an XRD pattern substantially as shown and illustrated in FIG. 6B.
